(19) United States
(12) Patent Application Publication
(10) Pub. No.: US 2003/0189261 A1
(43) Pub. Date: Oct. 9, 2003

(54) UNDER-BUMP-METALLURGY LAYER

(76) Inventors: Ho-Ming Tong, Taipei (TW); Chun-Chi Lee, Kaohsiung (TW); Jen-Kuang Fang, Pingtung Hsien (TW); Min-Lung Huang, Kaohsiung (TW); Ching-Huei Su, Kaohsiung (TW); Chao-Fu Weng, Tainan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,026

(22) Filed: Mar. 11, 2003

(30) Foreign Application Priority Data
Apr. 3, 2002 (TW) 91106694

(51) Int. Cl. H01L 21/44; H01L 23/48; H01L 23/52; H01L 29/40

(52) U.S. Cl. 257/780; 438/612; 438/686; 257/781

(57) ABSTRACT

An under-ball-metallurgy layer over a contact pad is provided. The contact pad and corresponding contact surface of the under-bump-metallurgy layer are made of copper. The under-ball-metallurgy layer is constructed from a stack of metallic layers selected from a group consisting of titanium/copper, titanium-tungsten alloy/copper, tantalum/copper, titanium/titanium-nitride compound/copper, tantalum/tantalum-nitride compound/copper, tantalum/nickel-vanadium alloy/copper, tantalum/nickel/copper, copper/nickel-vanadium alloy/copper, titanium/nickel/copper, copper/chromium-copper alloy/copper, or chromium-copper alloy/chromium/chromium-copper alloy/copper.

### CROSS REFERENCE TO RELATED APPLICATIONS

This application claims the priority benefit of Taiwan application serial no. 91106694, filed Apr. 03, 2002.

### BACKGROUND OF INVENTION

1. Field of Invention

The present invention relates to an under-bump-metallurgy layer. More particularly, the present invention relates to an under bump-metallurgy layer structure on a copper bonding pad.

2. Description of Related Art

In this information age, electronic products are used everywhere to facilitate our communication, business transactions, education, recreation and more. The principle drivers behind the creation of all these electrical devices are specially designed integrated circuits. As electronic technologies continue to advance, increasingly complex, functionally powerful and highly personalized electronic products are produced. Rapid progress in design also brings about the current trend of product miniaturization. In semiconductor manufacturing, line width of devices has steadily decreased from 0.25 μm to about 0.13 μm for the next generation of devices. However, serious problems often appear along with such reduction in the line width of metallic interconnects. For example, an overall increase in electrical resistance and current density is found in most of the metallic interconnects. An increase in current density will accelerate electromigration leading to a deterioration of device reliability. Electromigration is a phenomenon that occurs when a thin conductive line is subjected to an intense electric field. Metallic atoms along the grain boundary will migrate along the current-flow direction leading to a reduction in cross-section area along the metallic line. After some time, the metallic line may break and form an open circuit. The most common type of material for fabricating metallic lines is aluminum. Aluminum is often used because metallic lines are easily produced (by sputtering, evaporation, chemical vapor deposition) and shaped (by dry etching, wet etching). In addition, aluminum adheres firmly to a silicon dioxide layer. Nevertheless, aluminum has little resistance to electromigration and hence is not a suitable material for forming fine metallic interconnects. Moreover, aluminum has a higher electrical resistance relative to other material such as copper resulting in a higher resistance-capacitance delay in an integrated circuit.

To resist electromigration and reduce electrical resistance, metallic materials such as copper are now routinely employed. Earlier semiconductor manufacturers chose not to use copper as a material in the fabrication of metallic interconnects because of its high diffusion rate in contact with silicon or silicon dioxide so that some copper may eventually end up inside the substrate leading to deep energy gap problem. In addition, copper is an easily oxidized material and has the capacity to react with other materials at a relatively low temperature. The lack of an effective dry-etching technique for shaping copper lines also contributes to a cutback in its development. However, recent research in material properties and fabrication processes of copper has produced some breakthroughs, especially in damascene process and chemical-mechanical polishing. Nowadays, most silicon chips have copper bonding pads.

Furthermore, to miniaturize integrated circuit packages, many types of high-density semiconductor packages are developed. Miniaturization of packages is often achieved using a flip-chip technique. In the flip-chip technique, bumps are formed on the bonding pads of a chip. The chip is electrically connected to a substrate through the bumps. Compared with a wire-bond package or a tape automated bonding (TAB) package, a flip-chip package has the shortest overall circuit path and a high performance rating. Moreover, the backside of the chip may be exposed outside the flip chip package by design so that the heat dissipation rate from the chip can be increased. However, before putting copper pads on a chip, a matching under-ball-metallurgy layer structure capable of attaching a welding meteral firmly to a bonding pad must first be designed.

### SUMMARY OF INVENTION

Accordingly, one object of the present invention is to provide an under-ball-metallurgy layer for attaching a welding meteral firmly to a bonding pad made of copper and maintaining a good electrical connection between the two.

Before starting out to describe this invention, the spatial preposition “over” or “above” needs to be clarified. When the preposition “over” or “above” is used, the relationship between the two objects concerned may or may not have direct contact with each other. For example, an object A is “over” or “above” an object B may mean either object A is above object B and directly touching object B or object A is in the space above object B but without touching object B.

To achieve these and other advantages and in accordance with the purpose of the invention, as embodied and broadly described herein, the invention provides an under-ball-metallurgy layer that forms over a contact pad. The contact pad and corresponding contact surface of the under-bump-metallurgy layer are made of copper. The under-ball-metallurgy layer is constructed from a stack of metallic layers selected from a group consisting of titanium/copper, titanium-tungsten alloy/copper, tantalum/copper, titanium/titanium-nitride compound/copper, tantalum/tantalum-nitride compound/copper, tantalum/nickel-vanadium alloy/copper, tantalum/nickel/copper, copper/nickel vanadium alloy/copper, titanium/nickel/copper, copper/chromium-copper alloy/copper, or chromium-copper alloy/chromium/chromium-copper alloy/copper.

In brief, the under-ball-metallurgy layer structure according to this invention is able to correspond with other copper processing operations such that a bump is firmly attached to a copper bonding pad and a good electrical connection is established between the two.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a magnified cross-sectional view of an under-ball-metallurgy layer structure having two metallic layers sitting on top of a corresponding bump position on a wafer according to one preferred embodiment of this invention;

FIG. 2 is a magnified cross-sectional view of an under-ball-metallurgy layer structure having three metallic layers sitting on top of a corresponding bump position on a wafer according to one preferred embodiment of this invention; and

FIG. 3 is a magnified cross-sectional view of an under-ball-metallurgy layer structure having four metallic layers sitting on top of a corresponding bump position on a wafer according to one preferred embodiment of this invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

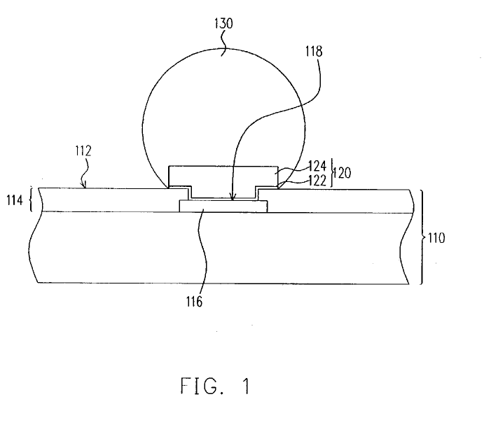

FIG. 1 is a magnified cross-sectional view of an under-ball-metallurgy layer structure having two metallic layers sitting on top of a corresponding bump position on a wafer according to one preferred embodiment of this invention. As shown in FIG. 1, a chip 110 having an active surface 112 is provided. The active surface 112 of the chip 110 has a passivation layer 114 and a plurality of bonding pads 116 (only one is shown). The passivation layer 114 exposes the bonding pads 116. The bonding pads 116 are fabricated using copper.

An under-ball-metallurgy layer 1120 sits on the surface of each bonding pad 116. In this embodiment, the under-ball-metallurgy layer 120 has two metallic layers, a first metallic layer 122 and a second metallic layer 124. The first metallic layer 122 covers the surface 118 of the bonding pad 116 and a portion of the passivation layer 114 surrounding the bonding pad 116. The second metallic layer 124 covers the first metallic layer 122. The first metallic layer 122 is fabricated using a material such as titanium, titanium-tungsten alloy or tantalum. The second metallic layer 124 is fabricated using a material such as gold, platinum, palladium, silver or copper. The second metallic layer 124 has a thickness between about 500 to 1000 μm. A welding meteral 130 sits over the under-ball-metallurgy layer 120 for attaching the chip 110 to a carrier (not shown), for example, a substrate. Through the welding meteral 130, the chip 110 and the carrier are electrically connected. The welding meteral 130 actually sits on top of the second metallic layer 124. The welding meteral 130 is fabricated using a substance such as lead-tin alloy, gold or lead-free alloy. Through the two-layered composite under-ball-metallurgy layer 120, not only are the bonding pad 116 and the welding meteral 130 firmly joined together, but a good electrical connection is also made between them.

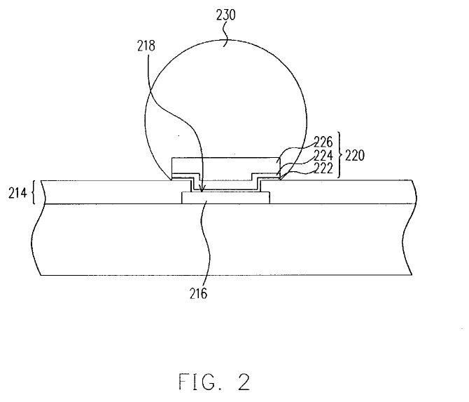

Although the aforementioned under-ball-metallurgy layer has a two-layered structure, this is by no means the only configuration allowed. FIG. 2 is a magnified cross-sectional view of an under-ball-metallurgy layer structure having three metallic layers sitting on top of a corresponding bump position on a wafer according to one preferred embodiment of this invention. As shown in FIG. 2, a three-layered under-ball-metallurgy layer 220 including a first metallic layer 222, a second metallic layer 224 and a third metallic layer 226, sits on top of the bonding pad 216. The first metallic layer 222 covers the surface 218 of the bonding pad 216 and a portion of the passivation layer 214 surrounding the bonding pad 216. The second metallic layer 224 covers the first metallic layer 222. The third metallic layer 226 covers the second metallic layer 224. A welding meteral 230 sits on top of the third metallic layer 226. The welding meteral is fabricated using a substance such as lead-tin alloy, gold or lead-free alloy. In general, the first metallic layer 222, the second metallic layer and the third metallic layer 226 are fabricated using different types of materials according to the following cases of applications.

In a first case, the first metallic layer 222 can be a titanium layer, the second metallic layer 224 can be a titanium-nitride compound and the material of the third metallic layer 226 can be gold, platinum, palladium, silver or copper. In a second case, the first metallic layer 222 can be a tantalum layer, the second metallic layer 224 can be a tantalum-nitride compound and the material of the third metallic layer 226 can be gold, platinum, palladium, silver or copper. In a third case, the first metallic layer 222 can be a tantalum layer, the second metallic layer 224 can be a layer of nickel-vanadium alloy and tha material of the third metallic layer 226 can be gold, platinum, palladium, silver or copper. In a fourth case, the first metallic layer 222 can be a tantalum layer, the second metallic layer 224 can be a nickel layer and the material of the third metallic layer 226 can be gold, platinum, palladium, silver or copper. In a fifth case, the first metallic layer 222 can be a copper layer, the second metallic layer 224 can be a layer of nickel-vanadium alloy and the material of the third metallic layer 226 can be gold, platinum, palladium, silver or copper. In a sixth case, the first metallic layer 222 can be a titanium layer, the second metallic layer 224 can be a nickel layer and the material of the third metallic layer 226 can be gold, platinum, palladium, silver or copper. In a seventh case, the first metallic layer 222 can be a copper layer, the second metallic layer 224 can be a layer of chromium-copper alloy and the material of the third metallic layer 226 can be gold, platinum, palladium, silver or copper. In all the aforementioned seven cases, the third metallic layer 226 preferably has a thickness between about 500 to 1000 μm. Through the three-layered composite under-ball-metallurgy layer 220, not only are the bonding pad 216 and the welding meteral 230 firmly joined together, but a good electrical connection is also made between them.

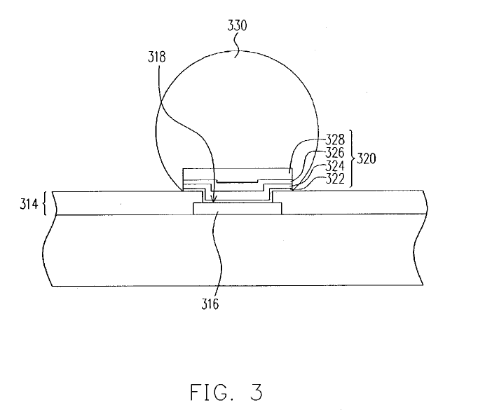

Aside from a two-layered or three-layered structure, a four-layered under-ball-metallurgy layer structure is also possible. FIG. 3 is a magnified cross-sectional view of an under-ball-metallurgy layer structure having four metallic layers sitting on top of a corresponding bump position on a wafer according to one preferred embodiment of this invention. As shown in FIG. 3, a four-layered under-ball-metallurgy layer 320 including a first metallic layer 322, a second metallic layer 324, a third metallic layer 326 and a fourth metallic layer 328 sits on top of a bonding pad 316. The first metallic layer 322 covers the surface 318 of the bonding pad 316 and a portion of the passivation layer 314 surrounding the bonding pad 316. The second metallic layer 324 covers the first metallic layer 322. The third metallic layer 326 covers the second metallic layer 324. Finally, the fourth metallic layer 328 covers the third metallic layer 326. A welding meteral 330 sits on top of the fourth metallic layer 328. The first metallic layer 322 is fabricated using a substance such as chromium-copper alloy; the second metallic layer 324 is fabricated using a substance such as chromium; the third metallic layer 326 is fabricated using a substance such as chromium-copper alloy and the fourth metallic layer 328 is fabricated using a substance such as gold, platinum, palladium, silver or copper. The welding meteral is fabricated using a substance such as lead-tin alloy, gold or lead-free alloy. In addition, the fourth metallic layer 328 preferably has a thickness between about 500 to 1000 μm.

In the aforementioned embodiments, the welding meteral serves as an external contact for the chip. However, the under-ball-metallurgy layer may form over other types of contact pad made of copper aside from the contact pad on a chip. For example, a redistribution circuit may form over a chip before forming the under-ball-metallurgy layer over the contact pads of a redistribution layer.

Furthermore, the atoms within various metallic layers may diffuse to neighboring metallic layers. For example, atoms within a first metallic layer may cross into a second metallic layer due to diffusion. Hence, the boundary between the first and the second metallic layer is generally fuzzy.

In summary, the under-ball-metallurgy layer according to this invention may have a variety of composite structures. They are listed out in Table 1.

TABLE 1

| Composite | | | | |
|---|---|---|---|---|
| under-ball- | | | | |
| metallurgy | | | | Fourth |
| layer | First metal | Second metal | Third metal | metal |
| structure | layer | layer | layer | layer |
| #1 | Titanium | gold, platinum, | — | — |
| | | palladium, | | |
| | | silver or | | |
| | | Copper | | |
| #2 | Titanium- | gold, platinum, | — | — |
| | tungsten | palladium, | | |
| | alloy | silver or | | |
| | | Copper | | |
| #3 | Tantalum | gold, platinum, | — | — |
| | | palladium, | | |
| | | silver or | | |
| | | Copper | | |
| #4 | Titanium | Titanium- | gold, platinum, | — |
| | | nitride | palladium, | |
| | | compound | silver or Copper | |
| #5 | Tantalum | Tantalum- | gold, platinum, | — |
| | | nitride | palladium, | |
| | | compound | silver or Copper | |
| #6 | Tantalum | Nickel- | gold, platinum, | — |
| | | vanadium alloy | palladium, | |
| | | | silver or Copper | |
| #7 | Tantalum | Nickel | gold, platinum, | — |
| | | | palladium, | |
| | | | silver or Copper | |
| #8 | Copper | Nickel- | gold, platinum, | — |
| | | vanadium alloy | palladium, | |
| | | | silver or Copper | |
| #9 | Titanium | Nickel | gold, platinum, | — |
| | | | palladium, | |
| | | | silver or Copper | |
| #10 | Copper | Chromium- | gold, platinum, | — |
| | | copper alloy | palladium, | |
| | | | silver or Copper | |
| #11 | Chro- | Chromium | Chromium- | gold, |
| | mium- | | copper alloy | platinum, |
| | copper | | | palladium, |
| | alloy | | | silver or |
| | | | | Copper |

All of the aforementioned composite under-ball-metallurgy structures permit firm attachment of a welding meteral onto a bonding pad made of copper and provide good electrical connection between the two.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An under-ball-metallurgy layer over a contact pad, wherein the contact pad and corresponding contact surface of the under ball-metallurgy layer are both made from copper, the under-ball-metallurgy layer comprising:
a first metallic layer over the contact pad, wherein the first metallic layer is fabricated using titanium; and
a second metallic layer over the first metallic layer, wherein the second metallic layer is fabricated using gold, platinum, palladium, silver or copper.

2. The under-ball-metallurgy layer of claim 1, wherein the second metallic layer has a thickness between about 500 to 1000 μm.

3. The under-ball-metallurgy layer of claim 1, wherein a welding meteral is also formed over the second metallic layer and the welding meteral is fabricated using a material selected from a group consisting of lead-tin alloy, gold and lead-free alloy.

4. An under-ball-metallurgy layer over a contact pad, wherein the contact pad and corresponding contact surface of the under-ball-metallurgy layer are both made from copper, the under-ball-metallurgy layer comprising:
a first metallic layer over the contact pad, wherein the first metallic layer is fabricated using titanium-tungsten alloy; and
a second metallic layer over the first metallic layer, wherein the second metallic layer is fabricated using gold, platinum, palladium, silver or copper.

5. The under-ball-metallurgy layer of claim 4, wherein the second metallic layer has a thickness between about 500 to 1000 μm.

6. The under-ball-metallurgy layer of claim 4, wherein a welding meteral is also formed over the second metallic layer and the welding meteral is fabricated using a material selected from a group consisting of lead-tin alloy, gold and lead-free alloy.

7. An under-ball-metallurgy layer over a contact pad, wherein the contact pad and corresponding contact surface of the under-ball-metallurgy layer are both made from copper, the under-ball-metallurgy layer comprising:
a first metallic layer over the contact pad, wherein the first metallic layer is fabricated using tantalum; and
a second metallic layer over the first metallic layer, wherein the second metallic layer is fabricated using gold, platinum, palladium, silver or copper.

8. The under-ball-metallurgy layer of claim 7, wherein the second metallic layer has a thickness between about 500 to 1000 μm.

9. The under-ball-metallurgy layer of claim 7, wherein a welding meteral is also formed over the second metallic layer and the welding meteral is fabricated using a material selected from a group consisting of lead-tin alloy, gold and lead-free alloy.

10. An under-ball-metallurgy layer over a contact pad, wherein the contact pad and corresponding contact surface of the under ball-metallurgy layer are both made from copper, the under-ball-metallurgy layer comprising:
a first metallic layer over the contact pad, wherein the first metallic layer is fabricated using titanium;
a second metallic layer over the first metallic layer, wherein the second metallic layer is fabricated using titanium-nitride compound; and
a third metallic layer over the second metallic layer, wherein the third metallic layer is fabricated using gold, platinum, palladium, silver or copper.

11. The under-ball-metallurgy layer of claim 10, wherein the third metallic layer has a thickness between about 500 to 1000 μm.

12. The under-ball-metallurgy layer of claim 10, wherein a welding meteral is also formed over the third metallic layer and that the welding meteral is fabricated using a material selected from a group consisting of lead-tin alloy, gold and lead-free alloy.

13. An under-ball-metallurgy layer over a contact pad, wherein the contact pad and corresponding contact surface of the under-ball-metallurgy layer are both made from copper, the under-ball-metallurgy layer comprising:
a first metallic layer over the contact pad, wherein the first metallic layer is fabricated using tantalum;
a second metallic layer over the first metallic layer, wherein the second metallic layer is fabricated using tantalum-nitride compound; and
a third metallic layer over the second metallic layer, wherein the third metallic layer is fabricated using gold, platinum, palladium, silver or copper.

14. The under-ball-metallurgy layer of claim 13, wherein the third metallic layer has a thickness between about 500 to 1000 μm.

15. The under-ball-metallurgy layer of claim 13, wherein a welding meteral is also formed over the third metallic layer and the welding meteral is fabricated using a material selected from a group consisting of lead-tin alloy, gold and lead-free alloy.

16. An under-ball-metallurgy layer over a contact pad, wherein the contact pad and corresponding contact surface of the under-ball-metallurgy layer are both made from copper, the under-ball-metallurgy layer comprising:
a first metallic layer over the contact pad, wherein the first metallic layer is fabricated using copper;
a second metallic layer over the first metallic layer, wherein the second metallic layer is fabricated using chromium-copper alloy; and
a third metallic layer over the second metallic layer, wherein the third metallic layer is fabricated using gold, platinum, palladium, silver or copper.

17. The under-ball-metallurgy layer of claim 16, wherein the third metallic layer has a thickness between about 500 to 1000 μm.

18. The under-ball-metallurgy layer of claim 13, wherein a welding meteral is also formed over the third metallic layer and the welding meteral is fabricated using a material selected from a group consisting of lead-tin alloy, gold and lead-free alloy.

19. An under-ball-metallurgy layer over a contact pad, wherein the contact pad and corresponding contact surface of the under-ball-metallurgy layer are both made from copper, the under-ball-metallurgy layer comprising:
a first metallic layer over the contact pad, wherein the first metallic layer is fabricated using tantalum;
a second metallic layer over the first metallic layer, wherein the second metallic layer is fabricated using nickel-vanadium alloy; and
a third metallic layer over the second metallic layer, wherein the third metallic layer is fabricated using gold, platinum, palladium, silver or copper.

20. The under-ball-metallurgy layer of claim 19, wherein the third metallic layer has a thickness between about 500 to 1000 μm.

21. The under-ball-metallurgy layer of claim 19, wherein a welding meteral is also formed over the third metallic layer and that the welding meteral is fabricated using a material selected from a group consisting of lead-tin alloy, gold and lead-free alloy.

22. An under-ball-metallurgy layer over a contact pad, wherein the contact pad and corresponding contact surface of the under-ball-metallurgy layer are both made from copper, the under-ball-metallurgy layer comprising:
a first metallic layer over the contact pad, wherein the first metallic layer is fabricated using tantalum;
a second metallic layer over the first metallic layer, wherein the second metallic layer is fabricated using nickel; and
a third metallic layer over the second metallic layer, wherein the third metallic layer is fabricated using gold, platinum, palladium, silver or copper.

23. The under-ball metallurgy layer of claim 22, wherein the third metallic layer has a thickness between about 500 to 1000 μm.

24. The under-ball-metallurgy layer of claim 22, wherein a welding meteral is also formed over the third metallic layer and that the welding meteral is fabricated using a material selected from a group consisting of lead-tin alloy, gold and lead-free alloy.

25. An under-ball-metallurgy layer over a contact pad, wherein the contact pad and corresponding contact surface of the under-ball-metallurgy layer are both made from copper, the under-ball-metallurgy layer comprising:
a first metallic layer over the contact pad, wherein the first metallic layer is fabricated using copper;
a second metallic layer over the first metallic layer, wherein the second metallic layer is fabricated using nickel-vanadium alloy; and
a third metallic layer over the second metallic layer, wherein the third metallic layer is fabricated using gold, platinum, palladium, silver or copper.

26. The under-ball-metallurgy layer of claim 25, wherein the third metallic layer has a thickness between about 500 to 1000 μm.

27. The under-ball-metallurgy layer of claim 25, wherein a welding meteral is also formed over the third metallic layer and the welding meteral is fabricated using a material selected from a group consisting of lead-tin alloy, gold and lead-free alloy.

28. An under-ball-metallurgy layer over a contact pad, wherein the contact pad and corresponding contact surface of the under-ball-metallurgy layer are both made from copper, the under-ball-metallurgy layer comprising:
a first metallic layer over the contact pad, wherein the first metallic layer is fabricated using titanium;
a second metallic layer over the first metallic layer, wherein the second metallic layer is fabricated using nickel; and
a third metallic layer over the second metallic layer, wherein the third metallic layer is fabricated using gold, platinum, palladium, silver or copper.

29. The under-ball-metallurgy layer of claim 28, wherein the third metallic layer has a thickness between about 500 to 1000 μm.

30. The under-ball-metallurgy layer of claim 28, wherein a welding meteral is also formed over the third metallic layer and that the welding meteral is fabricated using a material selected from a group consisting of lead-tin alloy, gold and lead-free alloy.

31. An under-ball-metallurgy layer over a contact pad, wherein the contact pad and corresponding contact surface of the under-ball-metallurgy layer are both made from copper, the under-ball metallurgy layer comprising:
a first metallic layer over the contact pad, wherein the first metallic layer is fabricated using chromium-copper alloy;
a second metallic layer over the first metallic layer, wherein the second metallic layer is fabricated using chromium;
a third metallic layer over the second metallic layer, wherein the third metallic layer is fabricated using chromium-copper alloy; and
a fourth metallic layer over the third metallic layer, wherein the fourth metallic layer is fabricated using gold, platinum, palladium, silver or copper.

32. The under-ball-metallurgy layer of claim 31, wherein the fourth metallic layer has a thickness between about 500 to 1000 μm.

33. The under-ball-metallurgy layer of claim 31, wherein a welding meteral is also formed over the fourth metallic layer and that the welding meteral is fabricated using a material selected from a group consisting of lead-tin alloy, gold and lead-free alloy.
